(19) United States
(12) Patent Application Publication
(10) Pub. No.: US 2026/0282952 A1
(43) Pub. Date: Sep. 17, 2026

(54) POWER MODULE

(71) Applicants: Hyundai Motor Company, Seoul (KR); Kia Corporation, Seoul (KR)

(72) Inventors: Han Jin DO, Hwaseong-Si (KR); Dong Hwan Lee, Hwaseong-Si (KR); Jin Myeong Yang, Hwaseong-Si (KR); Sung Won Park, Hwaseong-Si (KR)

(73) Assignees: Hyundai Motor Company, Seoul (KR); Kia Corporation, Seoul (KR)

(21) Appl. No.: 19/291,413

(22) Filed: Aug. 5, 2025

(30) Foreign Application Priority Data
Mar. 13, 2025 (KR) 10-2025-0032599

(51) Int. Cl. H10W 70/60; H10W 70/65; H10W 90/00

(52) U.S. Cl. CPC H10W 70/611; H10W 70/65; H10W 70/658; H10W 90/00; H10W 90/401; H10W 90/734

(57) ABSTRACT

A power module includes a plurality of first substrates, on each of which a first chip is disposed, a plurality of second substrates disposed to oppose the plurality of first substrates, and a signal lead including a signal pin connected to the first chip. At least a portion of the signal pin extends to a space between each of the first substrates disposed to be adjacent to each other.

### CROSS-REFERENCE TO RELATED APPLICATION(S)

The present application claims benefit of priority to Korean Patent Application No. 10-2025-0032599 filed on March 13, 2025 in the Korean Intellectual Property Office, the disclosure of which is incorporated herein by reference in its entirety.

### TECHNICAL FIELD

The present disclosure relates to a power module.

Recently, with growing interest in environmental issues, the number of eco-friendly vehicles equipped with electric motors as power sources has increased. Eco-friendly vehicles, also referred to as electric vehicles, include, as representative examples, electric vehicles (EVs) and hybrid electric vehicles (HEVs). An inverter for power control is used as a core component that significantly affects the performance and efficiency of these vehicles.

An inverter is a device converting direct current (DC) power into alternating current (AC) power, or converting AC power into DC power. The inverter may include a power module as a core component. The power module may be a switching element performing power conversion by handling high voltage and current. The power module includes a substrate and a power semiconductor chip. Power conversion may be performed through a switching operation of the power semiconductor chip.

### SUMMARY

An aspect of the present disclosure is to provide a power module which is advantageous for miniaturization and has improved electrical characteristics.

Another aspect of the present disclosure is to provide a power module having improved thermal reliability.

According to an aspect of the present disclosure, there is provided a power module including a plurality of first substrates, on each of which a first chip is disposed, a plurality of second substrates disposed to oppose the plurality of first substrates, and a signal lead including a signal pin connected to the first chip. At least a portion of the signal pin may extend to a space between each of the first substrates disposed to be adjacent to each other.

According to another aspect of the present disclosure, there is provided a power module including a plurality of first substrates, on each of which a first chip is disposed, a plurality of second substrates disposed to oppose the first substrate, and a signal lead including a signal pin connected to the first chip. At least a portion of the signal pin may extend to a space between each of the first substrates disposed to be adjacent to each other.

A power module according to example embodiments of the present disclosure may be advantageous for miniaturization and may have improved electrical characteristics.

The power module according to example embodiments of the present disclosure may have improved thermal reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top perspective view of a power module according to an example embodiment of the present disclosure;

FIG. 2 is a bottom perspective view of a power module according to an example embodiment of the present disclosure;

FIG. 3 is a plan view of an internal configuration of a molded portion of a power module according to an example embodiment of the present disclosure;

FIG. 4 is a plan view exemplarily illustrating a state in which a second substrate is removed from FIG. 3;

FIG. 5 is a cross-sectional view taken along line A-A’ of FIG. 1;

FIG. 6 is a cross-sectional view taken along line B-B’ of FIG. 1;

FIG. 7 is a plan view of an internal configuration of a molded portion of a power module according to another example embodiment of the present disclosure;

FIG. 8 is a plan view exemplarily illustrating a state in which a second substrate is removed from FIG. 7;

FIG. 9 is a cross-sectional view taken along line C-C’ of FIG. 7;

FIG. 10 is a plan view of an internal configuration of a molded portion of a power module according to another example embodiment of the present disclosure;

FIG. 11 is a plan view exemplarily illustrating a state in which a second substrate is removed from FIG. 10;

FIG. 12 is a cross-sectional view taken along line D-D’ of FIG. 10;

FIG. 13 is a cross-sectional view taken along line E-E’ of FIG. 10;

FIG. 14 is a perspective view of an internal configuration of a molded portion of a power module according to another example embodiment of the present disclosure;

FIG. 15 is a perspective view exemplarily illustrating a state in which a second substrate is separated from FIG. 14;

FIG. 16 is a cross-sectional view taken along line F-F’ of FIG. 14;

FIG. 17 is a plan view exemplarily illustrating an internal configuration of a molded portion of a power module according to another example embodiment of the present disclosure;

FIG. 18 is a plan view exemplarily illustrating a state in which a second substrate is removed from FIG. 17; and

FIG. 19 is a cross-sectional view taken along line G-G’ of FIG. 17.

### DETAILED DESCRIPTION

Various modifications may be made to the example embodiments. Here, the example embodiments are not construed as limited to the disclosure and should be understood to include all changes, equivalents, and replacements within the idea and the technical scope of the disclosure.

The terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component. The term “and/or” may include combinations of a plurality of related described items or any of a plurality of related described items.

The terms such as “unit,” “portion,” “part,” and the like may be used to describe various components, but the components should not be limited by the terms. The above-described terms may refer to a term indicating not only a physically/visually distinct component, but also a function or component of a corresponding portion even when not clearly divided or partitioned.

The terminology used herein is for describing particular example embodiments only and is not to be limiting of the example embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in an exemplary embodiment of the present disclosure, specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein, including technical or scientific terms, have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

In the description below, the terms “front,” “rear,” “upper,” “lower,” “top,” “bottom,” and the like used in relation to directions are defined based on the drawings.

Hereinafter, exemplary embodiments of the present disclosure will be described in more detail with reference to the accompanying drawings.

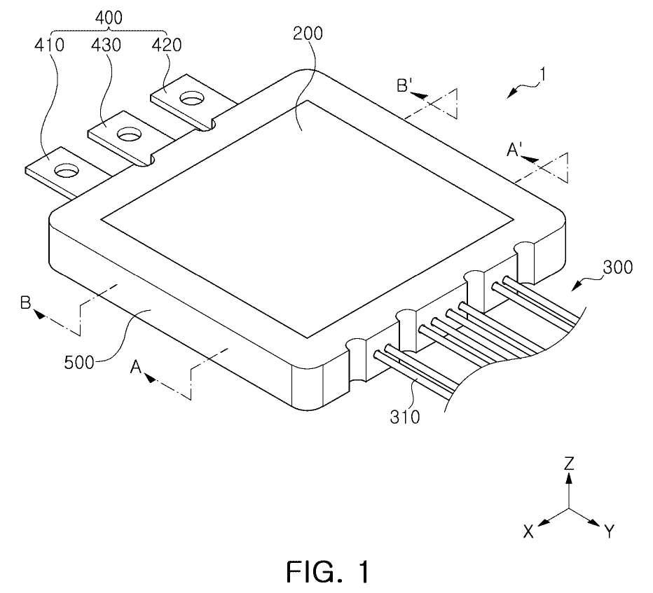

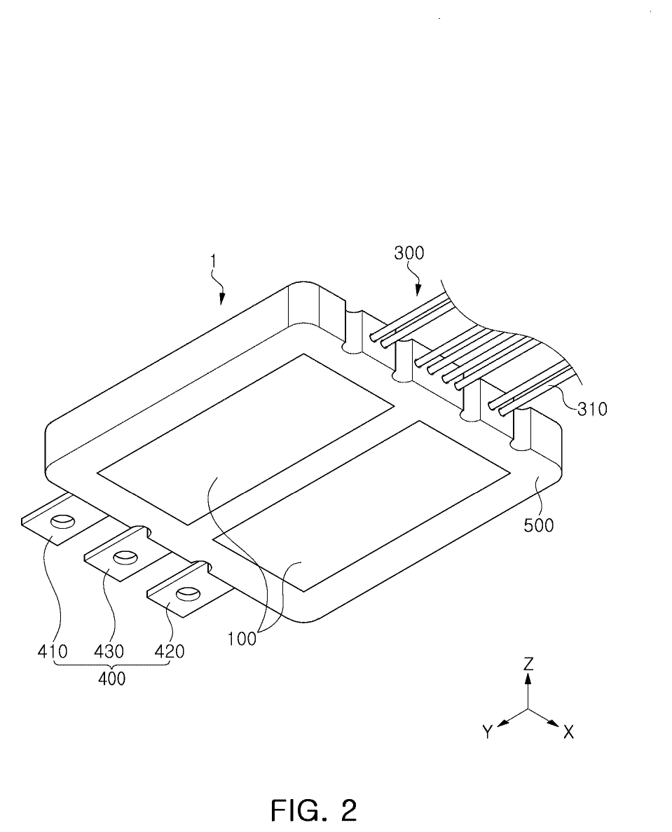

FIG. 1 is a top perspective view of a power module according to an example embodiment of the present disclosure. FIG. 2 is a bottom perspective view of a power module according to an example embodiment of the present disclosure.

Referring to FIGS. 1 and 2, a power module 1 according to an example embodiment of the present disclosure may include a first substrate 100, a second substrate 200, and a signal lead 300.

At least a portion of the first substrate 100 may be exposed to the outside of the molded portion 500. For example, one surface of the first substrate 100 may be exposed to a lower portion of the molded portion 500. The first substrate 100 may be disposed as a plurality of first substrates 100. The plurality of first substrates 100 may be disposed to be spaced apart from each other with a predetermined distance in a horizontal direction thereof. When the first substrate 100 is divided into a plurality of substrates, the power module 1 may have improved thermal reliability. In other words, when the first substrate 100 is divided into a plurality of substrates, the deformation of the substrate during operation of the power module 1 may be reduced, as compared to a case in which the first substrate 100 is disposed as a single substrate having an area the same as that of the plurality of substrates.

The second substrate 200 may be spaced apart from the first substrate 100. For example, the second substrate 200 may be spaced apart from the first substrate 100 with a predetermined distance in a vertical direction. Here, when the terms related to directions are defined, the vertical direction may refer to a Z-axis direction based on FIG. 1, and the horizontal direction may refer to an X-axis direction. At least a portion of the second substrate 200 may be exposed to the outside of the molded portion 500. For example, one surface of the second substrate 200 may be exposed to an upper portion of the molded portion 500.

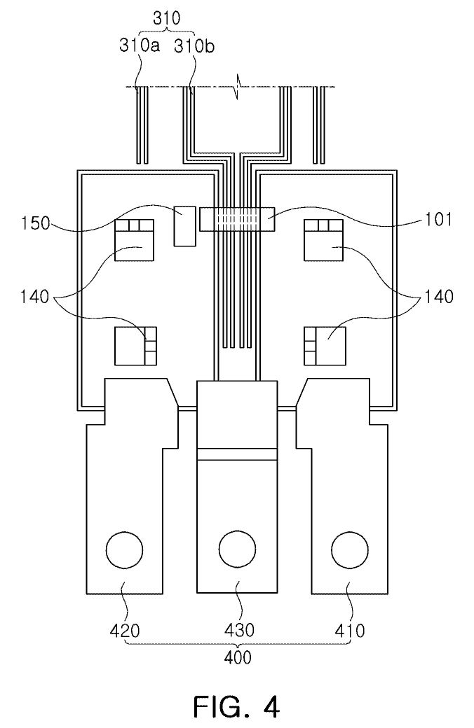

The signal lead 300 may be disposed to input a control signal to a chip 140 (see FIG. 4) disposed on the first substrate 100 or the second substrate 200 or to receive state information of the chip 140. The signal lead 300 may include a plurality of signal pins 310. One end portion of the signal pin 310 may be disposed on the inside of the molded portion 500, and the other end portion of the signal pin 310 may be exposed to the outside of the molded portion 500. The signal pin 310 may be electrically connected to the chip 140 in the molded portion 500. For example, the signal pin 310 may be connected to the chip 140 using a wire bonding method.

The power lead 400 may be provided to supply power to the chip 140 or to output power converted by the chip 140. The power lead 400 may include, for example, a first power terminal 410, a second power terminal 420, and a third power terminal 430. The first power terminal 410, the second power terminal 420, and the third power terminal 430 may be input terminals or output terminals. For example, the first power terminal 410 and the second power terminal 420 may be input terminals connected to a negative electrode and a positive electrode of the battery, respectively, and the third power terminal may be an output terminal through which converted power is output.

The molded portion 500 may form an external perimeter of the power module 1. The first substrate 100 and the second substrate 200 may be surrounded by the molded portion 500. The molded portion 500 may protect the chip 140 (see FIG. 4) from external moisture or impact. The molded portion 500 may improve coupling between the chip 140, the signal lead 300, and the power lead 400. The molded portion 500 may be provided using, for example, engineering plastic or epoxy molding compound (EMC).

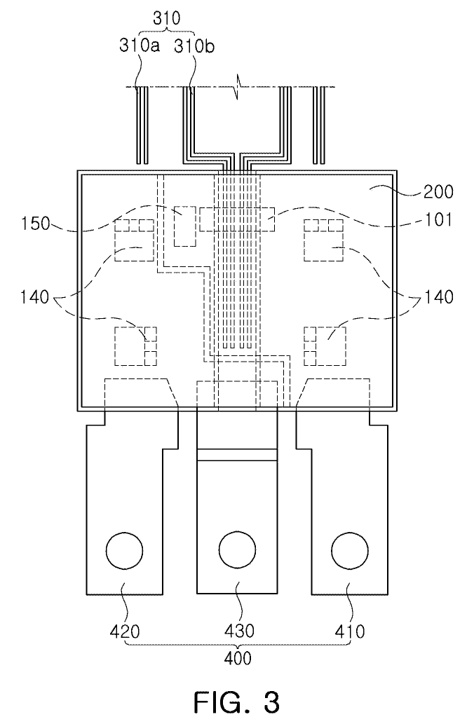

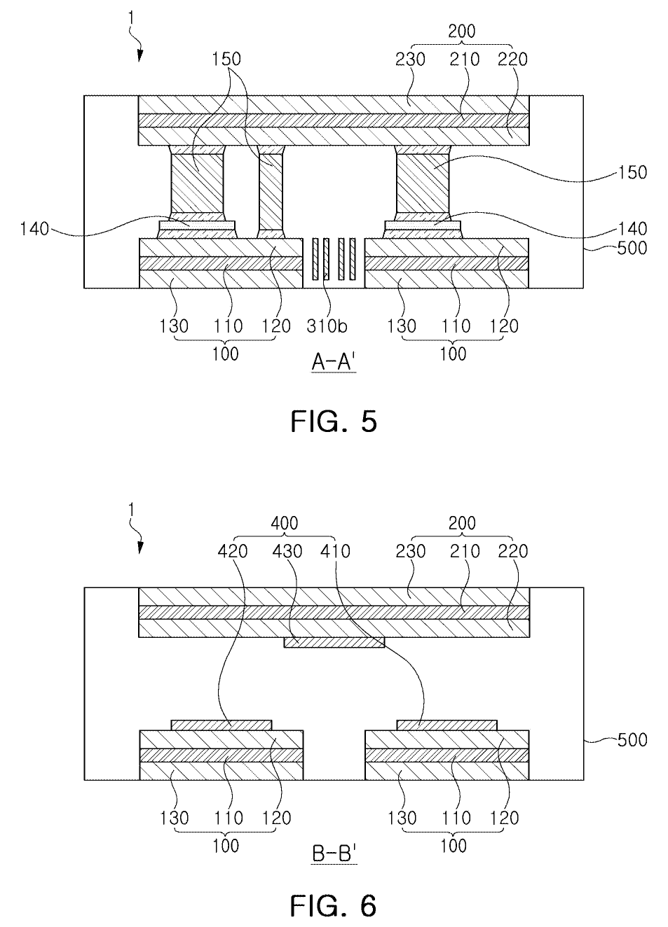

FIG. 3 is a plan view of an internal configuration of a molded portion of a power module according to an example embodiment of the present disclosure. FIG. 4 is a plan view exemplarily illustrating a state in which a second substrate is removed from FIG. 3. FIG. 5 is a cross-sectional view taken along line A-A’ of FIG. 1. FIG. 6 is a cross-sectional view taken along line B-B’ of FIG. 1.

Referring to FIGS. 3 to 6, the first substrate 100 may include a first insulating layer 110, a first internal metal layer 120, and a first external metal layer 130.

The first insulating layer 110 may include at least one of ceramic or polymer resin. For example, the first insulating layer 110 may include at least one of alumina, aluminum nitride, silicon nitride, epoxy, or polyimide. The first insulating layer 110 may be disposed on the inside of the molded portion 500. The first insulating layer 110 may include a plate shape, for example.

The first internal metal layer 120 may be disposed on one surface of the first insulating layer 110. The first internal metal layer 120 may be disposed on the inside of the molded portion 500. The first internal metal layer 120 may include a plurality of circuit lines. The circuit line of the first internal metal layer 120 may refer to a circuit pattern. The circuit line of the first internal metal layer 120 may be connected to at least one of the power lead 400 or the signal lead 300. The first internal metal layer 120 may be disposed as a conductor having high electrical conductivity. For example, the first internal metal layer 120 may include at least one of copper, aluminum, silver, or nickel. The first internal metal layer 120 may be formed using at least one of lamination, deposition, or plating. A method of forming the first internal metal layer 120 may be replaced using various methods commonly used in the technical field to which the present disclosure pertains.

The first external metal layer 130 may be disposed on the other surface of the first insulating layer 110. At least a portion of the first external metal layer 130 may be exposed to the outside of the molded portion 500. For example, the first external metal layer 130 may include at least one of copper or aluminum. The first external metal layer 130 may be formed using lamination, deposition, or plating. A method of forming the first external metal layer 130 may be replaced by various methods commonly used in the technical field to which the present disclosure pertains.

The first substrate 100 may be disposed as a plurality of first substrates 100. The plurality of first substrates 100 may be disposed to be spaced apart from each other with a predetermined distance in a horizontal direction. For example, the first substrate 100 may be disposed as two first substrates 100. The two first substrates 100 may be spaced apart from each other in the horizontal direction. At least a portion of the signal pin 310 may be disposed between the first substrates 100.

When the first substrate 100 is disposed as the plurality of first substrates 100, a bridge may be provided to electrically connect the first substrates 100, disposed to be adjacent to each other, to each other. The bridge may be formed of a conductive material. For example, the bridge may be formed of a copper block or an aluminum block.

At least one chip 140 may be disposed on the first substrate 100. The chip 140 may be electrically connected to the first internal metal layer 120. For example, the chip 140 may include at least one of an insulated gate bipolar transistor (IGBT), a compound semiconductor (SiC), a classifier circuit, a silicon-controlled rectifier (SCR), a power transistor, a MOS transistor, a power rectifier, a power regulator, or a diode. The chip 140 may be connected to the signal lead 300 and the power lead 400. The chip 140 may convert power supplied through the power lead 400 and output the converted power. For example, the chip 130 may receive DC power, convert the DC power into AC power, and output the AC power.

The second substrate 200 may include a second insulating layer 210, a second internal metal layer 220, and a second external metal layer 230. Detailed configurations of the second insulating layer 210, the second internal metal layer 220, and the second external metal layer 230 of the second substrate 200 may be substantially the same as those of the first insulating layer 110, the first internal metal layer 120, and the first external metal layer 130 of the first substrate 100.

At least a portion of the signal pin 310 may extend to a space between each of the first substrates 100 disposed to be adjacent to each other. For example, the signal pin 310 may include a first signal pin 310a corresponding to one side of the first substrate 100, and a second signal pin 310b extending to a space between each of the first substrates 100 disposed to be adjacent to each other. The second signal pin 310b may extend to a space between each of the first substrates 100 respectively including one end portions disposed to be adjacent to each other. The second signal pin 310b may include a straight line shape or may be bent at least once to correspond to a shape of an edge portion of the first substrate 100.

The second signal pin 310b may extend to a space between each of the first substrates 100 disposed to be adjacent to each other, and thus the power module 1 according to an example embodiment of the present disclosure may provide advantageous effects in terms of miniaturization and improvement in electrical characteristics. The power module 1 according to an example embodiment of the present disclosure may connect the chip 140, disposed to be adjacent to the first signal pin 310a, to the first signal pin 310a, and may connect the chip 140, disposed to be adjacent to the second signal pin 310b, to the second signal pin 310b. When there is no second signal pin 310b extending to a space between each of the first substrates 100, a circuit pattern may need to be added to the first substrate 100 to connect the chip 140 and the first signal pin 310a to each other. When the circuit pattern is added to connect the chip 140 to the first signal pin 310a, a current loop may become complex, degrading electrical characteristics and hindering miniaturization. The power module 1 according to an example embodiment of the present disclosure may include the second signal pin 310b extending to a space between each of the first substrates 100, and may connect the chip 140, disposed relatively far from the first signal pin 310a, to the second signal pin 310b, omitting an unnecessary circuit pattern. Accordingly, advantageous effects in terms of improved electrical characteristics and miniaturization may be achieved.

At least one via-spacer 150 may be provided between the first substrate 100 and the second substrate 200. The via-spacer 150 may electrically connect at least one of the first substrates 100 to the second substrate 200 to each other or electrically connect the chip 140 and the second substrate 200 to each other.

The power lead 400 may include a first power terminal 410, a second power terminal 420, and a third power terminal 430. For example, the first power terminal 410 may be connected to one of a plurality of first substrates 100, and the second power terminal 420 may be connected to another one of the plurality of first substrates 100. The third power terminal 430 may be connected to the second substrate. The first power terminal 410 and the second power terminal 420 may be input terminals, and the third power terminal 430 may be an output terminal. Input/output terminal configurations of the first power terminal 410, the second power terminal 420, and the third power terminal 430 may be changed.

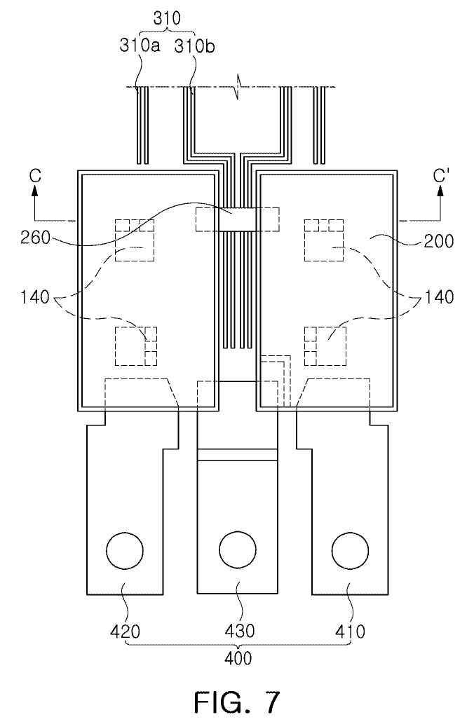

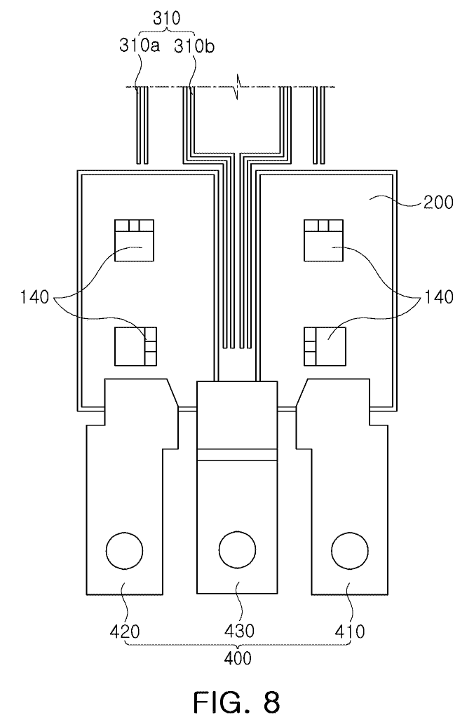

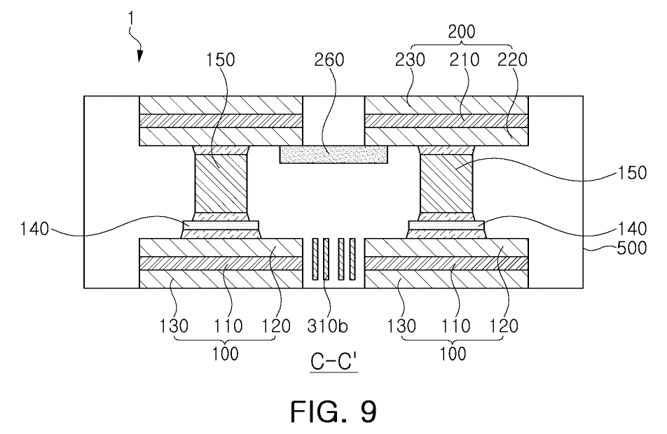

FIG. 7 is a plan view of an internal configuration of a molded portion of a power module according to another example embodiment of the present disclosure. FIG. 8 is a plan view exemplarily illustrating a state in which a second substrate is removed from FIG. 7. FIG. 9 is a cross-sectional view taken along line C-C’ of FIG. 7 (in which a molded portion is additionally illustrated for better understanding).

Referring to FIGS. 7 to 9, a power module 1 according to another example embodiment of the present disclosure may include a plurality of first substrates 100, a plurality of second substrates 200, and a signal lead 300. Except for a configuration of the second substrate 200, the power module 1 according to another example embodiment of the present disclosure may be substantially the same as the power module illustrated in FIGS. 1 to 6. Accordingly, detailed descriptions of the same configurations are omitted and replaced with the above descriptions.

At least a portion of the second substrate 200 may be exposed to the outside of a molded portion 500. For example, one surface of the second substrate 200 may be exposed to an upper portion of the molded portion 500. The second substrate 200 may be disposed as a plurality of second substrates 200. The plurality of second substrates 200 may be disposed to be spaced apart from each other with a predetermined distance in a horizontal direction. The plurality of second substrates 200 may be disposed to oppose the plurality of first substrates 100 in a vertical direction.

The second substrate 200 may include a second insulating layer 210, a second internal metal layer 220, and a second external metal layer 230. The second insulating layer 210 may include at least one of ceramic or polymer resin. For example, the second insulating layer 210 may include at least one of alumina, aluminum nitride, silicon nitride, epoxy, or polyimide. The second insulating layer 210 may be disposed on the inside of the molded portion 500. The second internal metal layer 220 may be disposed on one surface of the second insulating layer 210. The second internal metal layer 220 may be disposed on the inside of the molded portion 500. The second internal metal layer 220 may include a plurality of circuit lines. The circuit lines of the second internal metal layer 220 may refer to circuit patterns. The second internal metal layer 220 may be disposed as a conductor including high electrical conductivity. The second external metal layer 230 may be disposed on the other surface of the second insulating layer 210. At least a portion of the second external metal layer 230 may be exposed to the outside of the molded portion 500. For example, the second external metal layer 230 may include at least one of copper or aluminum.

The second substrates 200, disposed to be adjacent to each other, may be electrically connected to each other. For example, the second substrates 200, disposed to be adjacent to each other, may be electrically connected to each other through a bridge 260. The bridge 260 may be formed of a conductive material. For example, the bridge 260 may be disposed as a copper block or an aluminum block.

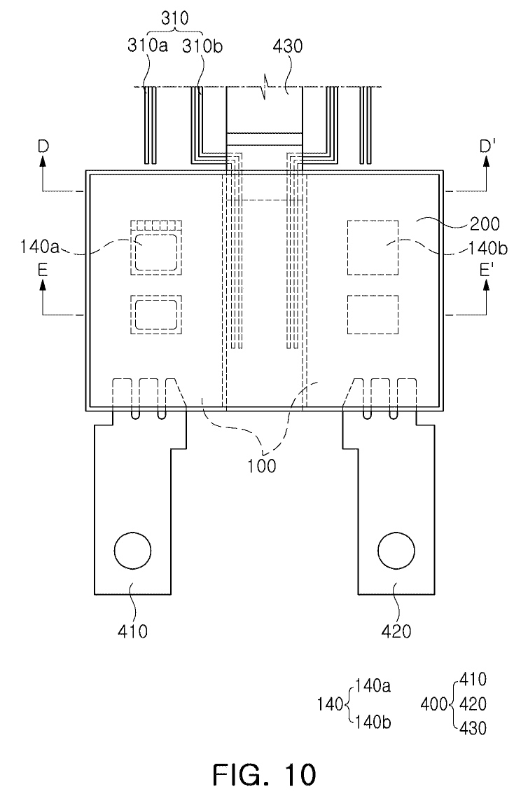

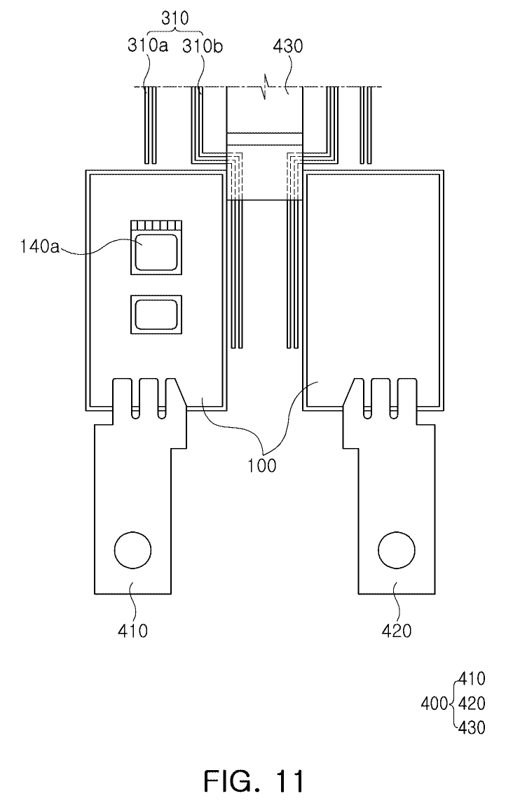

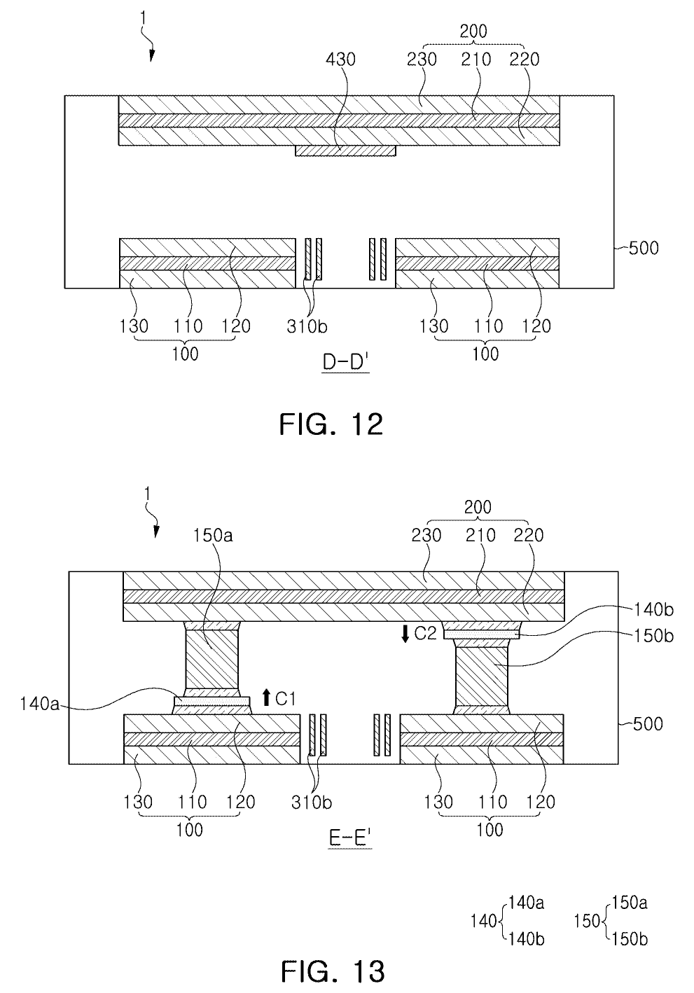

FIG. 10 is a plan view of an internal configuration of a molded portion of a power module according to another example embodiment of the present disclosure. FIG. 11 is a plan view exemplarily illustrating a state in which a second substrate is removed from FIG. 10. FIG. 12 is a cross-sectional view taken along line D-D’ of FIG. 10. FIG. 13 is a cross-sectional view taken along line E-E’ of FIG. 10 (in FIGS. 12 and 13, a molded portion is additionally illustrated for better understanding).

Referring to FIGS. 10 to 13, a power module 1 according to another example embodiment of the present disclosure may include a first substrate 100, a second substrate 200, and a signal lead 300. Except for an arrangement configuration of a chip 140, other configurations of the power module 1 according to another example embodiment of the present disclosure may be substantially the same as those of the power module illustrated in FIGS. 1 to 6. Accordingly, detailed descriptions of the same configurations are omitted and replaced with the above descriptions.

A power module 1 according to another example embodiment of the present disclosure may include a first substrate 100 and a second substrate 200. A chip 140 may be disposed on the first substrate 100 and the second substrate 200. The chip 140 may include a first chip 140a disposed on the first substrate 100, and a second chip 140b disposed on the second substrate 200.

The first chip 140a may be disposed on the first substrate 100. For example, the first chip 140a may be disposed on a surface of the first substrate 100 opposite to the second substrate 200. The first chip 140a may be electrically connected to a first internal metal layer 120 of the first substrate 100.

The second chip 140b may be disposed on the second substrate 200. For example, the second chip 140b may be disposed on one surface of the second substrate 200 opposite to the first substrate 100. The second chip 140b may be electrically connected to a second internal metal layer 220 of the second substrate 200.

A via-spacer 150 may be provided between the first substrate 100 and the second substrate 200. The via-spacer 150 may include a first via-spacer 150a including one end portion connected to one surface of the first chip 140a opposite to the second substrate 200 and the other end portion connected to one surface of the second substrate 200 opposite to the first chip 140a, and a second via-spacer 150b including one end portion connected to one surface of second chip 140b opposite to the first substrate 100 and the other end portion connected to one surface of the first substrate 100 opposite to the second chip 140b.

The power module 1 according to another example embodiment of the present disclosure may simplify a current loop by mounting the chip 140 on each of the first substrate 100 and the second substrate 200 and arranging the chip 140 in opposite vertical directions. A direction of a current flowing through the chip 140 may be formed in a single direction. In other words, a current may flow into the chip 140 through one surface of the chip 140 in contact with a substrate and flow out of the chip 140 through the other surface of the chip 140 not in contact with the substrate. That is, referring to FIG. 13, in the case of the first chip 140a, a current may flow from a lower portion to an upper portion of the first chip 140a (c1), and in the case of the second chip 140b, a current may flow from an upper portion to a lower portion of the second chip 140b (c2). Accordingly, the first chip 140a and the second chip 140b may be disposed on the first substrate 100 and the second substrate 200, respectively, to form a current loop. Accordingly, an unnecessary via-spacer or circuit pattern for forming the current loop may be omitted.

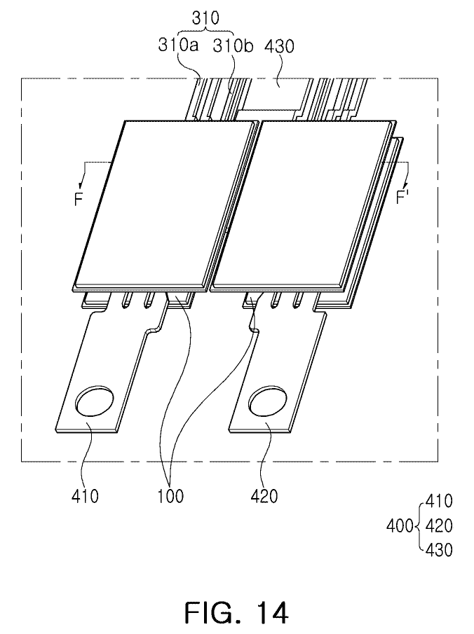

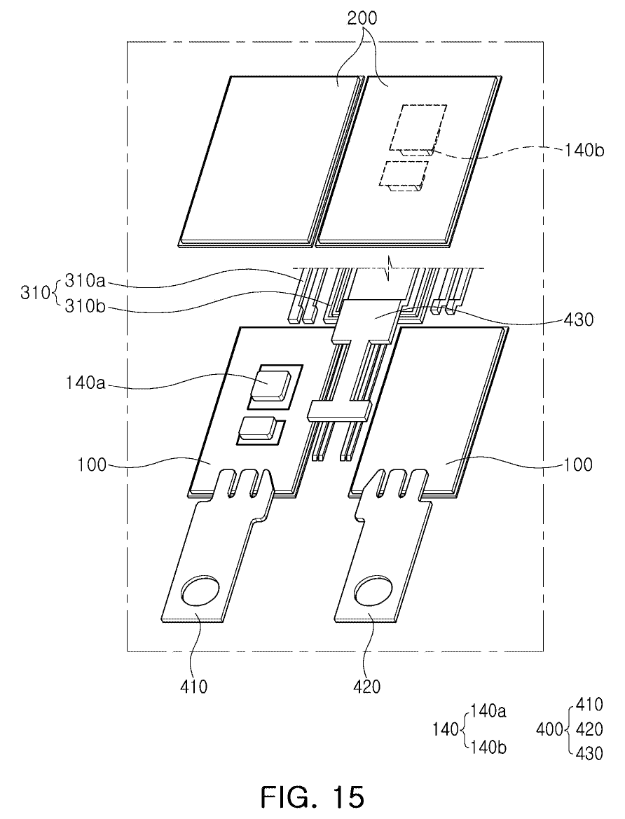

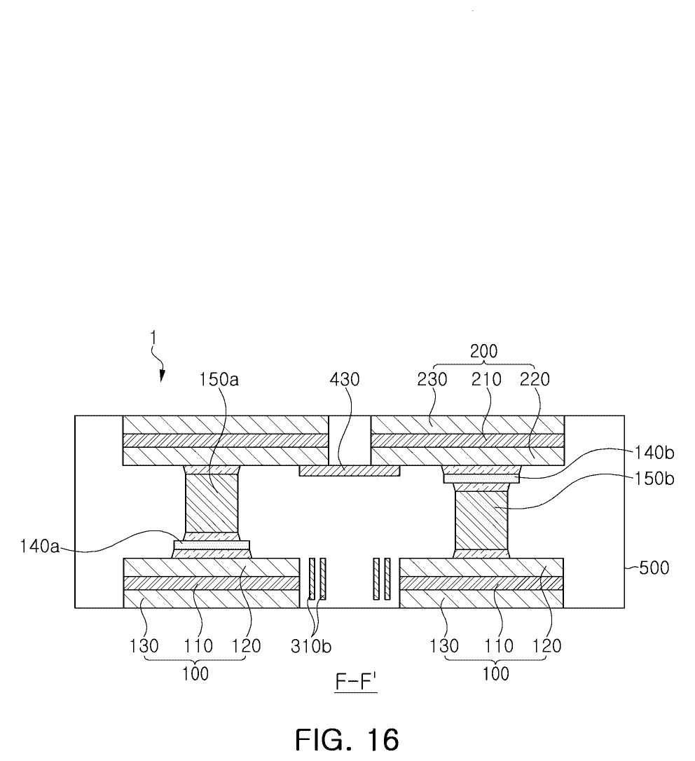

FIG. 14 is a perspective view of an internal configuration of a molded portion of a power module according to another example embodiment of the present disclosure. FIG. 15 is a perspective view exemplarily illustrating a state in which a second substrate is separated from FIG. 14. FIG. 16 is a cross-sectional view taken along line F-F’ of FIG. 14 (in FIG. 16, a molded portion is additionally illustrated for better understanding).

Referring to FIGS. 14 to 16, a power module 1 according to another example embodiment of the present disclosure may include a first substrate 100, a second substrate 200, a signal lead 300, and a power lead 400. Except for configurations of the second substrate 200 and the power lead 400, other configurations of the power module 1 according to another example embodiment of the present disclosure may be substantially the same as those of the power module illustrated in FIGS. 10 to 13. Accordingly, detailed descriptions of the same configurations are omitted and replaced with the above descriptions.

The second substrate 200 may be disposed as a plurality of second substrates 200. The plurality of second substrates 200 may be disposed to be spaced apart from each other with a predetermined distance in a horizontal direction. The plurality of second substrates 200 may be disposed to oppose a plurality of first substrates 100 in a vertical direction.

The second substrate 200 may include a second insulating layer 210, a second internal metal layer 220, and a second external metal layer 230. The second insulating layer 210 may include at least one of ceramic or polymer resin. For example, the second insulating layer 210 may include at least one of alumina, aluminum nitride, silicon nitride, epoxy, or polyimide. The second insulating layer 210 may be disposed on the inside of the molded portion 500. The second internal metal layer 220 may be disposed on one surface of the second insulating layer 210. The second internal metal layer 220 may be disposed on the inside of the molded portion 500. The second internal metal layer 220 may include a plurality of circuit lines. The circuit lines of the second internal metal layer 220 may refer to circuit patterns. The second internal metal layer 220 may be disposed as a conductor having high electrical conductivity. The second external metal layer 230 may be disposed on the other surface of the second insulating layer 210. At least a portion of the second external metal layer 230 may be exposed to the outside of the molded portion 500. For example, the second external metal layer 230 may include at least one of copper or aluminum.

A chip 140 may be disposed on the first substrate 100 and the second substrate 200. The chip 140 may include a first chip 140a disposed on the first substrate 100, and a second chip 140b disposed on the second substrate 200.

The first chip 140a may be disposed on the first substrate 100. For example, the first chip 140a may be disposed on one surface of the first substrate 100 opposite to the second substrate 200. The first chip 140a may be electrically connected to a first internal metal layer 120 of the first substrate 100.

The second chip 140b may be disposed on the second substrate 200. For example, the second chip 140b may be disposed on one surface of the second substrate 200 opposite to the first substrate 100. The second chip 140b may be electrically connected to the second internal metal layer 220 of the second substrate 200.

A via-spacer 150 may be provided between the first substrate 100 and the second substrate 200. The via-spacer 150 may include a first via-spacer 150a including one end portion connected to one surface of the first chip 140a opposite to the second substrate 200 and the other end portion connected to one surface of the second substrate 200 opposite to the first chip 140a, and a second via-spacer 150b including one end portion connected to one surface of second chip 140b opposite to the first substrate 100 and the other end portion connected to one surface of the first substrate 100 opposite to the second chip 140b.

The power lead 400 may be provided to supply power to the chip 140 or to output power converted by the chip 140. The power lead 400 may include a first power terminal 410, a second power terminal 420, and a third power terminal 430. The first power terminal 410 and the second power terminal 420 may be input terminals, and the third power terminal 430 may be an output terminal. Input/output terminal configurations of the first power terminal 410, the second power terminal 420, and the third power terminal 430 may be changed.

The first power terminal 410 may be connected to, for example, one of the plurality of first substrates 100. The second power terminal 420 may be connected to, for example, another one of a plurality of first substrates 100.

The third power terminal 430 may be connected to the second substrate. The third power terminal 430 may electrically connect the second substrates 200 disposed to be adjacent to each other. For example, the third power terminal 430 may be simultaneously connected to the second substrate 200 disposed to be adjacent to each other, electrically connecting the second substrate 200, disposed to be adjacent to each other, to each other.

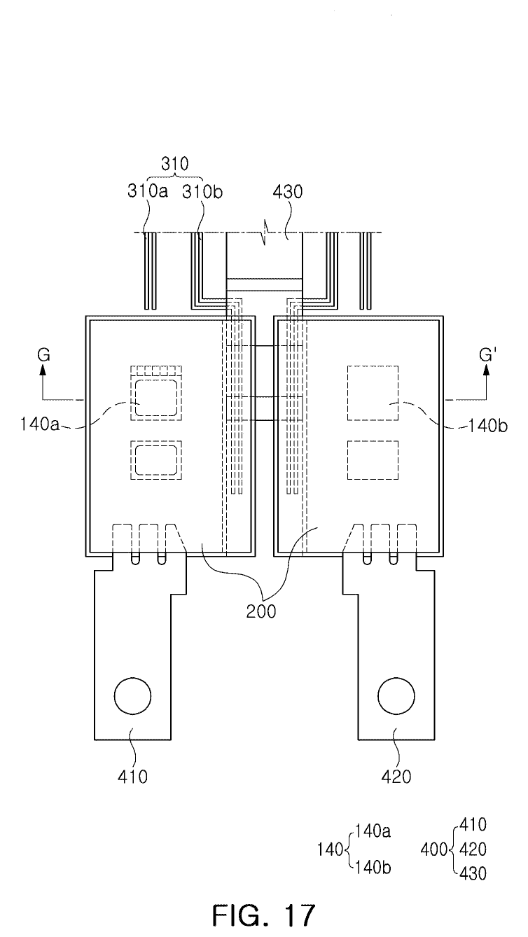

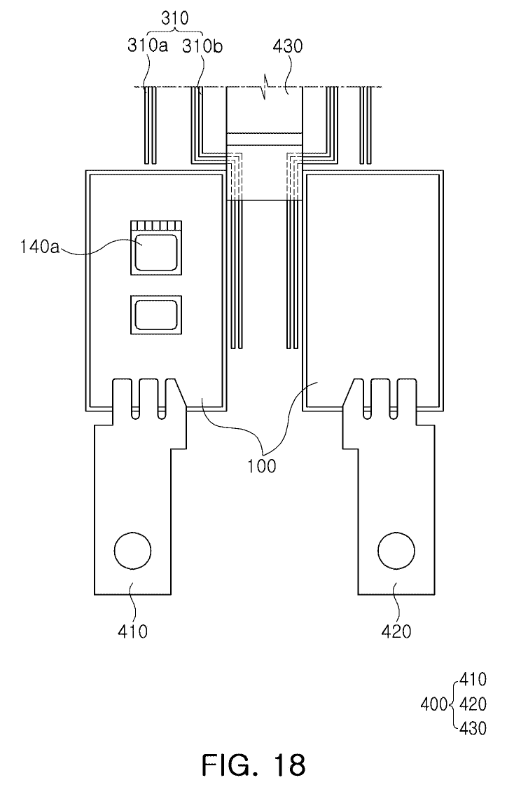

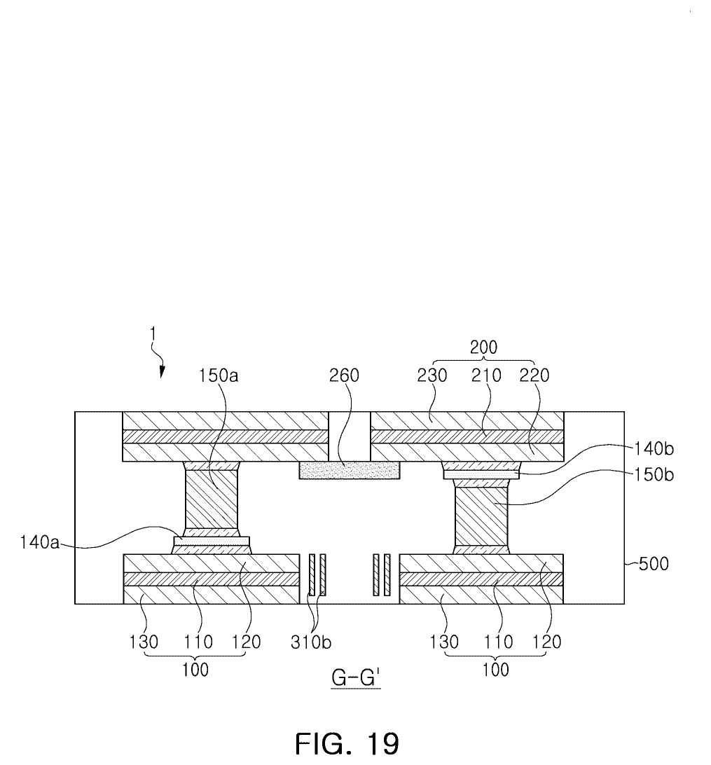

FIG. 17 is a plan view exemplarily illustrating an internal configuration of a molded portion of a power module according to another example embodiment of the present disclosure. FIG. 18 is a plan view exemplarily illustrating a state in which a second substrate is removed from FIG. 17. FIG. 19 is a cross-sectional view taken along line G-G’ of FIG. 17 (in FIG. 19, a molded portion is additionally illustrated for better understanding).

Referring to FIGS. 17 to 19, a power module 1 according to another example embodiment of the present disclosure may include a first substrate 100, a second substrate 200, a signal lead 300, and a bridge 260. Except for a configuration of the bridge 260, other configurations of the power module 1 according to another example embodiment of the present disclosure may be substantially the same as those of the power module illustrated in FIGS. 14 to 16. Accordingly, detailed descriptions of the same configurations are omitted and replaced with the above descriptions.

The second substrate 200 may be disposed as a plurality of second substrates 200. The plurality of second substrates 200 may be disposed to be spaced apart from each other with a predetermined distance in a horizontal direction. The plurality of second substrates 200 may be disposed to oppose a plurality of first substrates 100 in a vertical direction.

The second substrates 200, disposed to be adjacent to each other, may be electrically connected to each other. For example, the second substrates 200, disposed to be adjacent to each other, may be electrically connected to each other through the bridge 260. The bridge 260 may be formed of a conductive material. For example, the bridge 260 may be disposed as a copper block or an aluminum block.

A chip 140 may be disposed on the first substrate 100 and the second substrate 200. The chip 140 may include a first chip 140a disposed on the first substrate 100, and a second chip 140b disposed on the second substrate 200.

A via-spacer 150 may be provided between the first substrate 100 and the second substrate 200. The via-spacer 150 may include a first via-spacer 150a including one end portion connected to one surface of the first chip 140a opposite to the second substrate 200 and the other end portion connected to one surface of the second substrate 200 opposite to the first chip 140a, and a second via-spacer 150b including one end portion connected to one surface of second chip 140b opposite to the first substrate 100 and the other end portion connected to one surface of the first substrate 100 opposite to the second chip 140b.

The power lead 400 may be provided to supply power to the chip 140 or to output power converted by the chip 140. The power lead 400 may include a first power terminal 410, a second power terminal 420, and a third power terminal 430. The first power terminal 410 and the second power terminal 420 may be input terminals, and the third power terminal 430 may be an output terminal. Input/output terminal configurations of the first power terminal 410, the second power terminal 420, and the third power terminal 430 may be changed.

While example embodiments have been shown and described above, it will be apparent to those skilled in the art that modifications and variations could be made without departing from the scope of the present disclosure as defined by the appended claims.

What is claimed is:

1. A power module comprising:
a plurality of first substrates, on each of which a chip is disposed;
a second substrate disposed to oppose the plurality of first substrates; and
a signal lead including a signal pin connected to the chip,
wherein at least a portion of the signal pin extends to a space between each of the plurality of first substrates disposed to be adjacent to each other.

2. The power module of claim 1, further comprising:
a via-spacer electrically connecting at least one of the first substrates to the second substrate.

3. The power module of claim 1, further comprising:
a bridge electrically connecting the first substrates disposed to be adjacent to each other, to each other.

4. The power module of claim 1,
wherein the chip includes a second chip, and
wherein the second chip is disposed on one surface of the second substrate opposing one first substrate among the plurality of first substrates.

5. The power module of claim 4,
wherein the chip further includes a first chip, and
wherein the power module further includes:
a first via-spacer having a first end connected to one surface of the first chip opposing the second substrate at a side of one first substrate among the plurality of first substrates and a second end connected to one surface of the second substrate opposing the first chip at the side of the one first substrate among the plurality of first substrates; and
a second via-spacer having a first end connected to one surface of the second chip at a side of the other first substrate among the plurality of first substrates and a second end connected to one surface of the other first substrate opposing the second chip.

6. The power module of claim 1,
wherein the plurality of first substrates are provided to be spaced apart from each other by a predetermined distance in a horizontal direction of the power module, and
wherein the second substrate is disposed to oppose the plurality of first substrates in a vertical direction of the power module.

7. The power module of claim 1, further comprising:
a power lead supplying power to the chip or outputting power converted by the chip.

8. The power module of claim 7, wherein the power lead includes:
a first power terminal connected to one of the plurality of first substrates;
a second power terminal connected to the other one of the plurality of first substrates; and
a third power terminal connected to the second substrate.

9. A power module comprising:
a plurality of first substrates, on each of which a chip is disposed;
a plurality of second substrates disposed to oppose the plurality of first substrates; and
a signal lead including a signal pin connected to the chip;
wherein at least a portion of the signal pin extends to a space between each of the plurality of first substrates disposed to be adjacent to each other.

10. The power module of claim 9, further comprising:
a bridge electrically connecting the second substrates, disposed to be adjacent to each other, to each other.

11. The power module of claim 9,
wherein the chip includes a second chip, and
wherein the second chip is disposed on one surface of a corresponding second substrate opposing a corresponding first substrate.

12. The power module of claim 11,
wherein the chip includes a second chip, and
wherein the power module further comprises:
a first via-spacer having a first end connected to one surface of the first chip opposing one second substrate among the plurality of second substrates at a side of one first substrate among the plurality of first substrates and a second end connected to one surface of the one second substrate opposing the first chip at the side of the one first substrate among the plurality of first substrates; and
a second via-spacer having a first end connected to one surface of the second chip at a side of the other first substrate among the plurality of first substrates and a second end connected to one surface of the other first substrate opposing the second chip.

13. The power module of claim 9, wherein
the plurality of first substrates are provided to be spaced apart from each other by a predetermined distance in a horizontal direction of the power module,
the plurality of second substrates are provided to be spaced apart from each other by the predetermined distance in the horizontal direction, and
the plurality of second substrates are disposed to oppose the plurality of first substrates in a vertical direction of the power module.

14. The power module of claim 9, further comprising:
a power lead supplying power to the chip or outputting power converted by the chip.

15. The power module of claim 14, wherein the power lead includes:
a first power terminal connected to one of the plurality of first substrates;
a second power terminal connected to the other one of the plurality of first substrates; and
a third power terminal connected to the second substrates disposed to be adjacent to each other, the third power terminal electrically connecting the second substrates, disposed to be adjacent to each other, to each other.
